(19) United States
(12) Patent Application Publication
(10) Pub. No.: US 2014/0021987 A1
(43) Pub. Date: Jan. 23, 2014

(54) INJECTION-LOCKED-TYPE FREQUENCY-LOCKED OSCILLATOR

(71) Applicant: Kenichi Okada, Tokyo (JP)

(72) Inventor: Kenichi Okada, Tokyo (JP)

(73) Assignee: Semiconductor Technology Academic Research Center, Yokohama (JP)

(21) Appl. No.: 14/008,961

(22) PCT Filed: Mar. 12, 2012
(86) PCT No.: PCT/JP2012/056228

§ 371 Date: Sep. 30, 2013

(30) Foreign Application Priority Data
Mar. 31, 2011 (JP) 2011-077981

(51) Int. Cl. H03L 7/083

(52) U.S. Cl. CPC H03L 7/083
USPC 327/156

(57) ABSTRACT

Provided is an injection-locked-type frequency-locked oscillator capable of stable operation and exhibiting low phase noise. This injection-locked-type frequency-locked oscillator comprises: a locked loop (10) provided with a first injection-locked-type signal-controlled oscillator (14); and a second injection-locked-type signal-controlled oscillator (20). In the first injection-locked-type signal-controlled oscillator (14), an output frequency signal is made variable by an oscillation frequency control signal, and no reference clock signal is injected. In the second injection-locked-type signal-controlled oscillator (20), a reference clock signal corresponding to a reference clock signal of the locked loop (10) is injected, an oscillation frequency control signal corresponding to the same oscillation frequency control signal as the oscillation frequency control signal to the first injection-locked-type signal-controlled oscillation (14) is inputted, the circuit configuration is the same as that of the first injection-locked-type signal-controlled oscillator, and a desired frequency signal is outputted.

### TECHNICAL FIELD

The present invention relates to an injection-locked-type frequency-locked oscillator and, more specifically, to an injection-locked-type frequency-locked oscillator having low phase noise characteristics.

### BACKGROUND ART

Conventionally, a PLL using a low phase noise crystal oscillator as a reference clock signal is known. As a voltage-controlled oscillator (VCO) used in the PLL, there are an LC-type VCO and a ring-type VCO. In the case of an LC-type VCO, the phase noise is low, however, because of restrictions on the physical size of a coil or capacitor, it is difficult to reduce its area. In the case of a ring-type VCO, the physical size can be reduced at the time of construction, and therefore, it has an advantage in reducing the area. However, in the case of a PLL using a ring-type VCO, the phase noise of the VCO itself becomes predominant. That is, even if a low phase noise crystal oscillator is used as a reference clock signal, because of the influence of phase noise of the ring-type VCO, the phase noise of the PLL becomes large.

There is known a PLL that uses an injection-locked-type VCO, as a voltage-controlled oscillator, into which a signal of a crystal oscillator is injected and locked in order to reduce the phase noise of the PLL (Non-Patent Document 1, Non-Patent Document 2). FIG. 1 illustrates a block diagram for explaining a configuration of the PLL that uses the conventional injection-locked-type VCO such as this. As illustrated schematically, the PLL that uses the conventional injection-locked-type VCO includes a PLL part consisting of a phase comparator (PFD) 1, a charge pump (CP) 2, a low-pass filter (LPF) 3, an injection-locked-type VCO (IL-VCO) 4, and a divider (/N) 5, and a pulse generator 6 configured to inject and lock a reference clock signal to the injection-locked-type VCO 4. By inputting a reference clock signal and a feedback loop signal from the injection-locked-type VCO 4 to the phase comparator 1 and by inputting a signal based on the phase difference therebetween as an oscillation frequency control signal of the injection-locked-type VCO, an output frequency signal f₀ is locked to the reference clock signal. Then, by injecting and locking the reference frequency clock signal to the injection-locked-type VCO 4 via the pulse generator 6 in order to reduce the phase noise of the injection-locked-type VCO 4, an attempt is made to improve the phase noise of the injection-locked-type VCO 4.

### PRIOR ART DOCUMENT

### Non-Patent Document

Non-Patent Document 1: S. Lee, et al., “Low-Phase-Noise Wide-Frequency-Range Ring-VCO-Based Scalable PLL with Subharmonic Injection Locking in 0.18 μm CMOS”, IMS 2010
Non-Patent Document 2: C.-F. Liang, et al., “An Injection-Locked Ring PLL with Self-Aligned Injection Window”, ISSCC 2011

### SUMMARY OF THE INVENTION

### Problem to be Solved by the Invention

With the prior art as illustrated in FIG. 1, there has been a problem that injection locking is not stable. In the prior art, in order to make it easy for the injection-locked-type VCO 4 to be locked to the reference clock signal, i.e., to enter a lock range, the oscillation frequency in the free-run state of the injection-locked-type VCO 4 is adjusted in advance. Due to this, adjustment is made so that a desired output frequency signal whose frequency is a multiple of that of the reference clock signal is obtained. However, if the injection-locked-type VCO 4 enters the locked state once, the frequency is pulled toward the injection locking side and fixed to a multiple of that of the reference clock frequency at all times, and therefore, the PLL no longer functions. Then, for example, if the lock range of the injection-locked-type VCO 4 deviates because of fluctuations in temperature, power source voltage, etc., the frequency is locked to a frequency near the end of the lock range, and therefore, a state where the lock is easily disengaged is brought about. However, in the prior art, even if the frequency deviates and is locked to a frequency near the end of the lock range, the PLL does not function, and therefore, it is not possible to detect this. Then, when the injection locking is disengaged, the PLL begins to function for the first time, and therefore, there has been a case where injection locking does not become stable. This is a problem that cannot be ignored particularly when a clock signal, etc., is generated.

The present invention has been made in view of such circumstances and an object thereof is to provide a low phase noise injection-locked-type frequency-locked oscillator capable of stable operation. Further, it is also possible to provide an injection-locked-type frequency-locked oscillator whose area can be reduced.

### Means for Solving the Problem

In order to achieve the above-mentioned object of the present invention, the injection-locked-type frequency-locked oscillator according to the present invention includes: a locked loop to which a reference clock signal is input and having at least a first injection-locked-type signal-controlled oscillator in which an output frequency signal is made variable by an oscillation frequency control signal and into which no reference clock signal is injected, and a comparator configured to compare an output of the first injection-locked-type signal-controlled oscillator and the reference clock signal and to determine the comparison result as an oscillation frequency control signal; and a second injection-locked-type signal-controlled oscillator into which a reference clock signal corresponding to the reference clock signal of the locked loop is injected and also to which an oscillation frequency control signal corresponding to the same oscillation frequency control signal as the oscillation frequency control signal to the first injection-locked-type signal-controlled oscillator is input, and which has the same circuit configuration as that of the first injection-locked-type signal-controlled oscillator, and which outputs a desired frequency signal.

It is only necessary for the first and the second injection-locked-type signal-controlled oscillator to be a ring-type voltage-controlled oscillator or an LC-type voltage-controlled oscillator, respectively.

Further, it is only necessary for the first and the second injection-locked-type signal-controlled oscillator to be a voltage-controlled oscillator whose oscillation frequency control signal is a voltage or a current-controlled oscillator whose oscillation frequency control signal is a current, respectively.

Further, it is only necessary for the locked loop to be a PLL or FLL.

Further, it is only necessary for the locked loop to be a PLL or FLL including an up-down counter and a digital-to-analog converter.

Further, it is only necessary to inject the reference clock signal of the locked loop to the second injection-locked-type signal-controlled oscillator via the pulse oscillator.

Further, a frequency offset compensation unit may be included and it may also be possible for the frequency offset compensation unit to offset the oscillation frequency control signal to the first injection-locked-type signal-controlled oscillator and the oscillation frequency control signal to the second injection-locked-type signal-controlled oscillator in order to compensate for the offset of the output frequency signals of the first injection-locked-type signal-controlled oscillator and the second injection-locked-type signal-controlled oscillator.

It may also be possible for the frequency offset compensation unit to intermittently offset the oscillation frequency control signal to the first injection-locked-type signal-controlled oscillator and the oscillation frequency control signal to the second injection-locked-type signal-controlled oscillator. Alternatively, it may also be possible to intermittently offset them at irregular intervals.

Further, it may also be possible for the second injection-locked-type signal-controlled oscillator to consist of a plurality of injection-locked-type signal-controlled oscillators so that desired frequency signals are output from the injection-locked-type signal-controlled oscillators, respectively.

### Effect of the Invention

The injection-locked-type frequency-locked oscillator of the present invention has an advantage of being capable of stable operation and being a low phase noise injection-locked-type frequency-locked oscillator. Further, there is also an advantage that the area can be reduced.

### BRIEF DESCRIPTION OF THE DRAWINGS

FIG. 1 is a block diagram for explaining a configuration of a PLL using a conventional injection-locked-type VCO.

FIG. 2 is a block diagram for explaining a configuration of an injection-locked-type frequency-locked oscillator of the present invention.

FIG. 3 is a block diagram for explaining an example in which a locked loop of the injection-locked-type frequency-locked oscillator of the present invention is controlled digitally.

FIG. 4 is a block diagram for explaining an example in which the injection-locked-type frequency-locked oscillator of the present invention has a frequency offset compensation unit.

FIG. 5 is a block diagram for explaining a frequency offset compensation unit the power consumption of which has been reduced of the injection-locked-type frequency-locked oscillator of the present invention.

FIG. 6 is a block diagram for explaining an example in which an output frequency signal of the injection-locked-type frequency-locked oscillator of the present invention is divided into a plurality of signals and distributed.

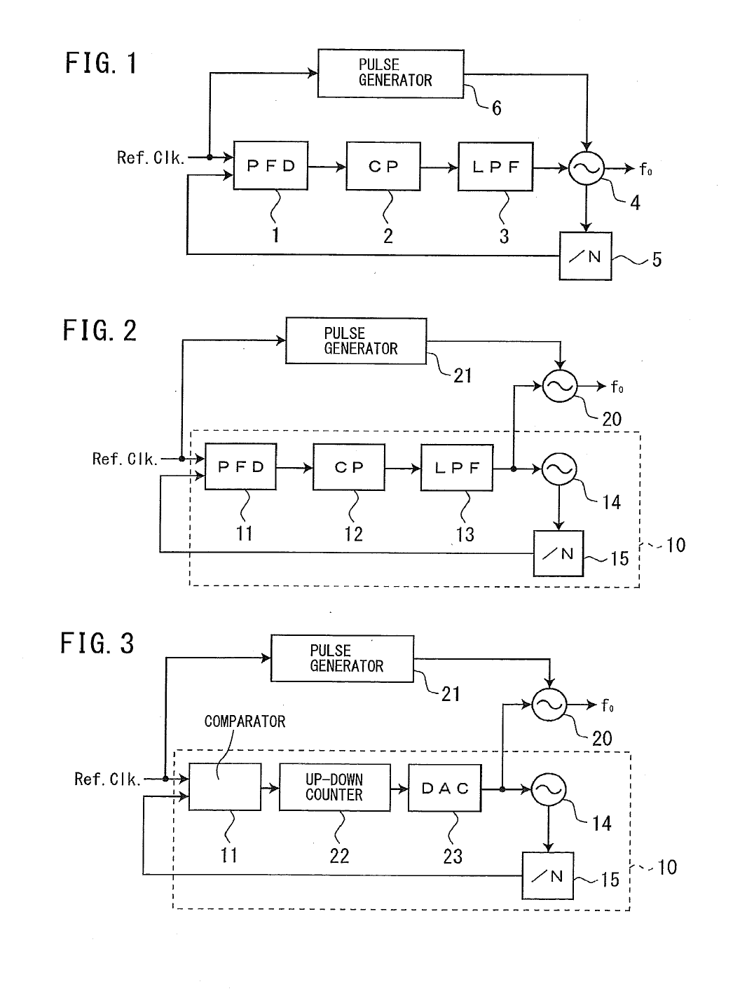

### EMBODIMENTS FOR CARRYING OUT THE INVENTION

Hereinafter, embodiments of the present invention are explained together with illustrated examples. FIG. 2 is a block diagram for explaining a configuration of an injection-locked-type frequency-locked oscillator of the present invention. As illustrated schematically, the injection-locked-type frequency-locked oscillator of the present invention mainly consists of a locked loop 10 and a second injection-locked-type signal-controlled oscillator 20.

To the locked loop 10, a reference clock signal (Ref. Clk.) is input. Then, the locked loop 10 includes a first injection-locked-type signal-controlled oscillator 14 and a comparator 11 as its main components. The comparator 11 is configured to compare an output of the first injection-locked-type signal-controlled oscillator 14 and the reference clock signal and to determine the result as an oscillation frequency control signal. In the illustrated example, an example in which a PLL (phase-locked loop) is used as a locked loop and a phase comparator (PFD) is used as a comparator is explained. As illustrated schematically, the locked loop 10 includes the comparator 11 (PFD), a charge pump (CP) 12, a low-pass filter (LPF) 13, the first injection-locked-type signal-controlled oscillator 14, and a divider (/N) 15. It may also be possible to regard the charge pump 12 as being included in the comparator 11. The phase comparator 11 configured to compare phases as a comparator is used to compare the phase of the output of the first injection-locked-type signal-controlled oscillator 14 and the phase of the reference clock signal, specifically, the phase of a low phase noise signal from, for example, a crystal oscillator, and to determine the phase difference as an oscillation frequency control signal. More specifically, in the case of a PLL, a feedback loop signal from the first injection-locked-type signal-controlled oscillator 14 is multiplied by 1/N by the divider 15 and input to the comparator 11. In the comparator 11, the phase of the signal is compared with the phase of the reference clock signal, in the charge pump 12, the phase difference signal is converted from a digital signal into an analog signal, and the phase difference is input as the oscillation frequency control signal of the first injection-locked-type signal-controlled oscillator 14 via the low-pass filter 13 configured to cut unwanted frequency components in the feedback loop. In the case of the illustrated example, the first injection-locked-type signal-controlled oscillator 14 is an injection-locked-type voltage-controlled oscillator (IL-VCO).

Further, as a locked loop, it is also possible to use, for example, an FLL (frequency-locked loop) other than the PLL. In this case, as a comparator, a frequency comparator is used. The frequency comparator uses a counter as a divider and the counter is configured so as to be reset at fixed intervals. It may also be possible to compare the values of the counter at the time of the reset timing and to use its result as the oscillation frequency control signal.

In the first injection-locked-type signal-controlled oscillator 14, the output frequency signal is made variable by the oscillation frequency control signal. In the injection-locked-type frequency-locked oscillator of the present invention, a reference clock signal is not injected into the first injection-locked-type signal-controlled oscillator 14. That is, the oscillation frequency is not locked by injection locking but by the locked loop 10.

Then, the second injection-locked-type signal-controlled oscillator 20 is configured to output the desired frequency signal f₀. Into the second injection-locked-type signal-controlled oscillator 20, a reference clock signal corresponding to the reference clock signal of the locked loop 10 is injected. More specifically, into the second injection-locked-type signal-controlled oscillator 20, the reference clock signal to be input to the locked loop 10 is injected via a pulse generator 21. The pulse generator 21 is configured to generate a pulse signal from an input signal (sinusoidal wave signal). By the pulse generator 21, the duty ratio is reduced and a pulse signal having a short ON operation time is generated and injected into the second injection-locked-type signal-controlled oscillator 20, and thereby, spurious noise is reduced.

The second injection-locked-type signal-controlled oscillator 20 oscillates at a frequency an integer times the frequency locked with the reference clock signal to be injected and an output frequency signal having low phase noise at about the same level of that of the reference clock signal is obtained. The important point of the present invention is that to the second injection-locked-type signal-controlled oscillator 20, the same oscillation frequency control signal as the oscillation frequency control signal to the first injection-locked-type signal-controlled oscillator 14 is input, and thereby, the output frequency signal is made variable. That is, the oscillation frequency control signal to the first injection-locked-type signal-controlled oscillator 14 is branched and is also input to the second injection-locked-type signal-controlled oscillator 20. Then, the second injection-locked-type signal-controlled oscillator 20 has the same circuit configuration as that of the first injection-locked-type signal-controlled oscillator 14. By causing the first and the second injection-locked-type signal-controlled oscillator to have the same circuit configuration, the configuration becomes such that similar frequency signals are output if the oscillation frequency control signal is the same. Consequently, the first and the second injection-locked-type signal-controlled oscillator enter the locked state. Further, into the second injection-locked-type signal-controlled oscillator 20, the reference clock signal is injected, and therefore, the output frequency signal having the low phase noise at about the same level as that of the reference clock signal is obtained as a result. In the illustrated example, the second injection-locked-type signal-controlled oscillator 20 is also illustrated as an injection-locked-type voltage-controlled oscillator (IL-VCO).

That is, the injection-locked-type frequency-locked oscillator of the present invention uses two injection-locked-type signal-controlled oscillators having the same configuration and configured so as to be operated by the same oscillation frequency control signal. Then, into the first injection-locked-type signal-controlled oscillator 14, no reference clock signal is injected and into the second injection-locked-type signal-controlled oscillator 20, the reference clock signal is injected while being locked by the locked loop 10. That is, in the injection-locked-type frequency-locked oscillator, the two signal-controlled oscillators are divided into one that performs injection locking and the other used in the locked loop. Then, while locking the first injection-locked-type signal-controlled oscillator 14 by the locked loop 10, its oscillation frequency control signal is input to the second injection-locked-type signal-controlled oscillator 20 into which the reference clock signal is injected. Due to this, the second injection-locked-type signal-controlled oscillator 20 operates highly stably with the control signal being optimum at all times. Even if the lock range of one of the signal-controlled oscillators deviates due to the fluctuations in temperature characteristics or the fluctuations in power source voltage, the oscillation frequency control signal also deviates in accordance with the deviation, and therefore, the other signal-controlled oscillator controlled by the oscillation frequency control signal also deviates in the same manner, resulting in the continuation of the stable operation.

Next, the operation of the injection-locked-type frequency-locked oscillator of the present invention configured as described above is explained more specifically. Explanation is given on the assumption that, for example, the reference clock signal has a frequency of 40 MHz and a desired output frequency signal has a frequency of 400 MHz. These specific frequencies are mere examples and in the present invention, the frequencies are not limited to these numerical values. The loop of the locked loop 10 is designed so as to have a band wide to a certain extent so that the locked loop 10 is easily locked with the reference clock signal. The first injection-locked-type signal-controlled oscillator 14 is configured so as to oscillate at about 400 MHz in the free-run state. Then, the frequency is multiplied by 1/10 by the divider 15 and the locked loop 10 is brought into the locked state. On the other hand, the second injection-locked-type signal-controlled oscillator 20 is configured so as to oscillate at about 400 MHz in the free-run state. When the reference clock signal is input, the locked loop 10 is clocked with the reference clock signal, and a frequency signal locked in the vicinity of 400 MHz is output and input to the phase comparator 11 via the feedback loop. On the other hand, to the second injection-locked-type signal-controlled oscillator 20 also, the reference clock signal is input and a frequency signal in the vicinity of 400 MHz locked with the reference clock signal is output. At this time, the oscillation frequency control signal of the locked loop 10, i.e., the output of the low-pass filter 13 is also input to the second injection-locked-type signal-controlled oscillator 20, and therefore, the second injection-locked-type signal-controlled oscillator 20 will be highly stable as the reference clock signal in the state where the locked loop 10 continues to function at all times.

The first and the second injection-locked-type signal-controlled oscillator 14 and 20 may also be configured by the ring-type voltage-controlled oscillator (ring-type VCO), respectively. They may also be configured by the LC-type VCO, however, in the case of the LC-type VCO, there are restrictions on the size of the passive element etc. However, in the case of the ring-type VCO, a plurality (odd number) of inverters is connected in the form of a ring and the area can be reduced. However, the ring-type VCO generally has high phase noise, and therefore, in the case where the general PLL is used, the phase noise of the VCO becomes predominant and as explained above relating to the prior art, the phase noise of the PLL becomes large. In the case of the injection-locked-type frequency-locked oscillator of the present invention, however, in the injection-locked-type signal-controlled oscillator that outputs a desired frequency signal, the ring-type VCO is locked with the reference clock signal by injection locking, and therefore, the phase noise of the reference clock signal becomes predominant and even in the case of the ring-type VCO, it is possible to suppress the phase noise of the output frequency signal very low.

The injection-locked-type frequency-locked oscillator is not limited to the voltage-controlled oscillator and may be the current-controlled oscillator. According to the oscillation frequency of the output signal, the linearity of the control code, etc., the current-controlled oscillator may be used appropriately.

In the illustrated example described above, the example in which the PLL is used as the locked loop is explained. However, the present invention is not limited to this example and it is also possible to use the FLL (frequency-locked loop) as described above. Further, for example, a digital PLL, a digital FLL, etc., may be used as long as it is configured to compare the output of the first injection-locked-type signal-controlled oscillator and the reference clock signal and to determine its result as an oscillation frequency control signal. That is, the locked loop may be any one that uses a signal-controlled oscillator configured to output some sort of digital code signal in accordance with the phase difference, to use the digital code signal as an oscillation frequency control signal, and to output an oscillation frequency based thereon.

FIG. 3 illustrates a block diagram for explaining an example in which the locked loop of the injection-locked-type frequency-locked oscillator of the present invention is controlled digitally. In the diagram, the portion to which the same symbol as that in FIG. 2 is attached represents the same portion and duplicated explanation is omitted.

As illustrated schematically, in this example, in place of the charge pump 12 and the low-pass filter 13 illustrated in FIG. 2, an up-down counter 22 and a digital-to-analog converter (DAC) 23 are used. In this illustrated example, the comparator 11 (PFD) compares the phases of the feedback loop signal from the divider 15 and the reference clock signal and the up-down counter 22 outputs a counter value based on the frequency difference and the phase difference. Then, this counter value is converted into an analog signal by the DAC 23 and input to the first and the second injection-locked-type signal-controlled oscillator 14 and 20 as an oscillation frequency control signal.

As described above, since the configuration in which a passive element such as a low-pass filter, is not used, the area can be further reduced.

In the examples illustrated in FIG. 2 and FIG. 3 described above, the output of the low-pass filter and the output of the digital-to-analog converter are branched and input to the two injection-locked-type signal-controlled oscillators as an oscillation frequency control signal. However, the present invention is not limited to these examples and, for example, the output of the comparator may be branched and the charge pump and the low-pass filter may be provided at each branching path, or the up-down counter and the digital-to-analog converter may be provided at each branching path. That is, what is required is to input the oscillation frequency control signal corresponding to the same oscillation frequency control signal as the oscillation frequency control signal to the first injection-locked-type signal-controlled oscillator, and it is not necessarily required for the control signal to be perfectly the same. In the illustrated example described above, the example is illustrated in which the PFD is used as the comparator 11, however, the present invention is not limited to this and, for example, a frequency comparator may be used. In this case, a counter is used as the divider and configured so as to be reset at regular intervals, and the result of the comparison of the values of the counter at the time of the reset timing may be used as an oscillation frequency control signal.

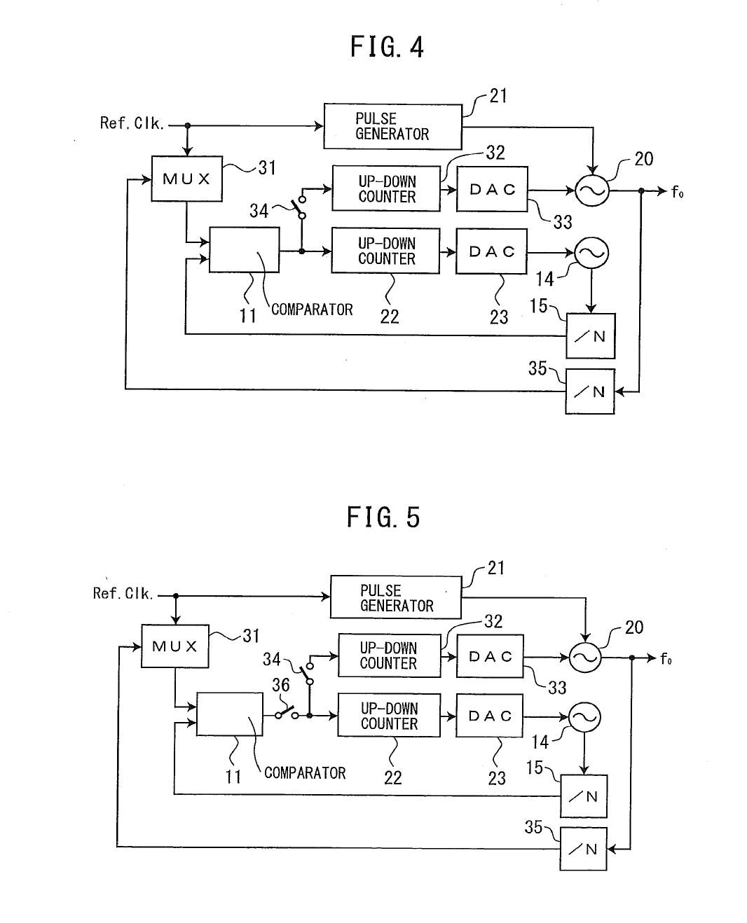

Next, an example is explained, in which the injection-locked-type frequency-locked oscillator of the present invention has a frequency offset compensation unit configured to compensate for the variation between two injection-locked-type signal-controlled oscillators. The injection-locked-type frequency-locked oscillator of the present invention uses two injection-locked-type signal-controlled oscillators and there is a case where a deviation between the oscillation frequencies occurs resulting from the manufacturing variation, the difference in the position where each injection-locked-type frequency-locked oscillator is arranged, etc. A configuration for compensating for the deviation is explained using FIG. 4. FIG. 4 is a block diagram for explaining an example in which the injection-locked-Lype frequency-locked oscillator of the present invention has a frequency offset compensation unit. In the diagram, the portion to which the same symbol as that in FIG. 3 is attached represents the same portion. In this example, there is provided a frequency offset compensation unit configured to compensate for a deviation between the output frequency signals by offsetting the oscillation frequency control signal to the first injection-locked-type signal-controlled oscillator 14 and the oscillation frequency control signal to the second injection-locked-type signal-controlled oscillator 20 in order to compensate for an offset of the output frequency signal of the first injection-locked-type signal-controlled oscillator 14 and the second injection-locked-type signal-controlled oscillator 20. The difference from the example illustrated in FIG. 3 lies in that there are further provided a multiplexer (MUX) 31, an up-down counter 32, a digital-to-analog converter (DAC) 33, a switch 34, and a divider (/N) 35. By using these units, the configuration is designed so that the output of the DAC 23, which is the oscillation frequency control signal to the first injection-locked-type signal-controlled oscillator 14 and the output of the DAC 33, which is the oscillation frequency control signal to the second injection-locked-type signal-controlled oscillator 20 are offset so as to compensate for the deviation between the output frequency signals. That is, in the example illustrated in FIG. 3, the output of the same DAC is input to each signal-controlled oscillator as the oscillation frequency control signal, however, in the example illustrated in FIG. 4, the deviation between the output frequency signals is compensated for by performing offsetting using two DACs.

In the following, the operation of the frequency offset compensation unit is explained. First, the first injection-locked-type signal-controlled oscillator 14 and the second injection-locked-type signal-controlled oscillator 20 are caused to operate at frequencies in the vicinity of the oscillation frequencies, respectively. Then, by the MUX 31, the feedback loop via the divider 35 is selected from the second injection-locked-type signal-controlled oscillator 20. At this time, the switch 34 is turned off and the phase difference signal from the comparator 1 to the second injection-locked-type signal-controlled oscillator 20 is cut. In this state, the output frequency signal of the second injection-locked-type signal-controlled oscillator 20 and the feedback loop signal from the first injection-locked-type signal-controlled oscillator 14 are input to the phase comparator 11 and based on the phase difference, the up-down counter 22 operates as a result, and therefore, the output voltage of the DAC 23, i.e., the oscillation frequency control signal changes until the oscillation frequencies of the first and the second injection-locked-type signal-controlled oscillator 14 and 20 become the same. From this state, the reference clock signal is set so as to be input to the comparator 11 by the MUX 31 and also the switch 34 is turned on. Due to this, the output voltages of the DAC 23 and the DAC 33 become the oscillation frequency control signals in the state of being offset by the amount corresponding to the variation between the first injection-locked-type signal-controlled oscillator 14 and the second injection-locked-type signal-controlled oscillator 20. That is, by using the oscillation frequency control signal, the offset of the output frequency signal of each of the signal-controlled oscillators 14 and 20 is compensated for. In the illustrated example also, the example in which the PFD is used as the comparator 11 is illustrated, however, the present invention is not limited to this and, for example, a frequency comparator may be used.

Further, a configuration for reducing power consumption of the above-described frequency offset compensation unit is explained. FIG. 5 is a block diagram for explaining a frequency offset compensation unit whose power consumption is reduced of the injection-locked-type frequency-locked oscillator of the present invention. In the diagram, the portion to which the same symbol as that in FIG. 4 is attached represents the same portion. The difference from the example illustrated in FIG. 4 lies in that a switch 36 is provided. By causing the up-down counters 22 and 32 to operate intermittently by using the switch 36, an attempt to reduce power consumption is made.

In the following, the operation of the frequency offset compensation unit in the illustrated example is explained. In the illustrated example, by causing the switch 36 to perform the turning on and off operation, the up-down counters 22 and 32 are caused to operate intermittently. That is, the configuration is designed so that the oscillation frequency control signal to the first injection-locked-type signal-controlled oscillator 14 and the oscillation frequency control signal to the second injection-locked-type signal-controlled oscillator 20 are offset intermittently. When the switch 36 is in the on state, as in the example illustrated in FIG. 4, the up-down counters 22 and 32 operate based on the phase difference from the comparator and the output voltage of the DACs 23 and 33, i.e., the oscillation frequency control signal changes until the oscillation frequencies of the first and the second injection-locked-type signal-controlled oscillator 14 and 20 become the same. At this time, the output voltage of the DACs 23 and 33 becomes the oscillation frequency control signal in the state of being offset by the amount corresponding to the variation between the first injection-locked-type signal-controlled oscillator 14 and the second injection-locked-type signal-controlled oscillator 20. Further, when the switch 36 is in the off state, from the DAC 33, the oscillation frequency control signal immediately before the switch 36 turns off is output continuously. At this time, the up-down counters 22 and 32 are not in operation, and therefore, it is possible to make an attempt to reduce power consumption. Further, at this time, it is not necessary to operate the first injection-locked-type signal-controlled oscillator 14. Consequently, with the configuration such as this, it is possible to reduce power consumption while compensating for the deviation between the output frequency signals by performing offsetting intermittently by causing the switch to perform turning on and off operation at predetermined intervals. As offset compensation, it is sufficient for the switch 36 to be turned on at about 10 to 100 cycles of the 1,000 to 10^{x} cycles (x≧3) of the locked loop. Here, x may be a sufficiently large value. Further, the timing with which offsetting is performed intermittently is not required to be a fixed interval. By performing offsetting intermittently at irregular intervals, it is also possible to prevent the spurious of the offset timing itself from riding on the output frequency signal.

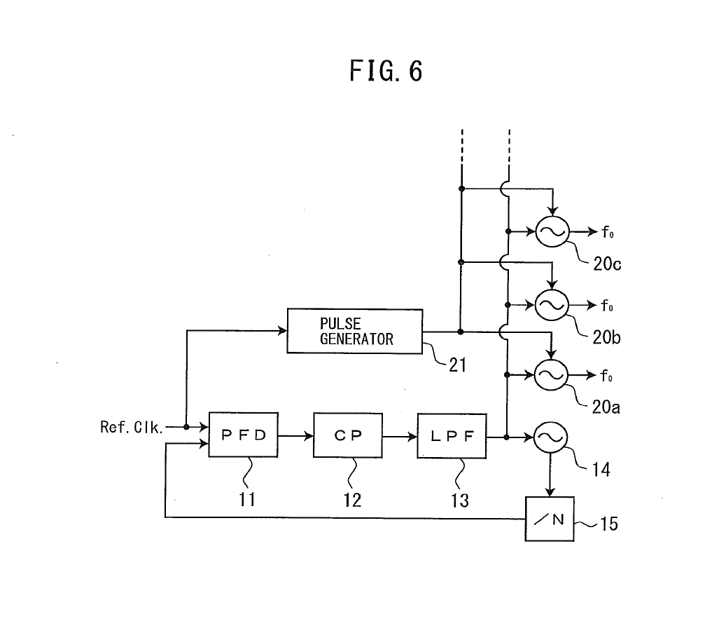

In the illustrated example described above, the example in which two injection-locked-type signal-controlled oscillators are used is explained, however, it may also be possible to configure the injection-locked-type frequency-locked oscillator of the present invention so that a plurality of output frequency signals is distributed by using more injection-locked-type signal-controlled oscillators. FIG. 6 is a block diagram for explaining the example in which a plurality of output frequency signals of the injection-locked-type frequency-locked oscillator of the present invention is distributed. In the diagram, the portion to which the same symbol as that in FIG. 2 is attached represents the same portion. As illustrated schematically, in this example, the second injection-locked-type signal-controlled oscillator in the example illustrated in FIG. 2 consists of a plurality of injection-locked-type signal-controlled oscillators 20a, 20b, 20c, . . . . To each of the plurality of the injection-locked-type signal-controlled oscillators 20a, 20b, 20c, . . . , the same oscillation frequency control signal as the oscillation frequency control signal to the first injection-locked-type signal-controlled oscillator is input and also the reference clock signal is injected via the pulse generator 21. Further, to each of the plurality of the injection-locked-type signal-controlled oscillators 20a, 20b, 20c, . . . , the oscillation frequency control signal, which is the output of the low-pass filter 13, is branched and input. Because of this, from each of the plurality of the injection-locked-type signal-controlled oscillators 20a, 20b, 20c, . . . , a desired frequency signal is output, and therefore, it is possible to distribute a plurality of desired output frequency signals. In the illustrated example, the output of the pulse generator 21 is branched and injected into the plurality of the injection-locked-type signal-controlled oscillators 20a, 20b, 20c, . . . , however, the present invention is not limited to this and it may also be possible to branch the reference clock signal into a plurality of signals and to provide a plurality of pulse generators to receive the signals, and then, to inject the signals into the plurality of the injection-locked-type signal-controlled oscillators.

In the example illustrated in FIG. 6, the locked loop has the configuration as illustrated in FIG. 2, however, the present invention is not limited to this and even to the configuration using the up-down counter and DAC as illustrated in FIG. 3, it is possible to apply the configuration in which a plurality of desired output frequencies is distributed.

By designing the configuration such as this, for example, it is made possible to extend a signal line in the low-frequency band to a block that requires an output frequency signal and which is located at a distant position, and to output a frequency signal in the high-frequency band at the position to which the signal lined is extended. Consequently, it is no longer necessary to route a signal line in the high-frequency band generally hard to handle, and therefore, a stable operation is enabled.

The injection-locked-type frequency-locked oscillator of the present invention is not limited to only the illustrated examples described above and it is obvious that various modifications can be made in the scope not deviating from the gist of the present invention.

### EXPLANATIONS OF REFERENCE NUMERALS

10 locked loop
11 phase comparator
12 charge pump
13 low-pass filter
14 first injection-locked-type signal-controlled oscillator
15, 35 divider
20 second injection-locked-type signal-controlled oscillator
21 pulse generator
22, 23 up-down counter
34, 36 switch

1. A injection-locked-type frequency-locked oscillator comprising:
a locked loop to which a reference clock signal is input and including a first injection-locked-type signal-controlled oscillator in which an output frequency signal is made variable by an oscillation frequency control signal and into which the reference clock signal is not injected, and a comparator configured to compare an output of the first injection-locked-type signal-controlled oscillator and the reference clock signal and to determine the result as an oscillation frequency control signal; and
a second injection-locked-type signal-controlled oscillator into which a reference clock signal corresponding to the reference clock signal of the frequency-locked loop is injected and also an oscillation frequency control signal corresponding to the same oscillation frequency control signal as the oscillation frequency control signal to the first injection-locked-type signal-controlled oscillator is input, having the same circuit configuration as that of the first injection-locked-type signal-controlled oscillator, and configured to output a desired frequency signal.

2. The injection-locked-type frequency-locked oscillator according to claim 1, wherein
the first and the second injection-locked-type signal-controlled oscillator are a ring-type voltage-controlled oscillator or LC-type voltage-controlled oscillator, respectively.

3. The injection-locked-type frequency-locked oscillator according to claim 1, wherein
the first and the second injection-locked-type signal-controlled oscillator include a voltage-controlled oscillator in which the oscillation frequency control signal is a voltage or a current-controlled oscillator in which the oscillation frequency control signal is a current, respectively.

4. The injection-locked-type frequency-locked oscillator according to claim 1, wherein
the locked loop is a PLL or FLL.

5. The injection-locked-type frequency-locked oscillator according to claim 4, wherein
the locked loop is a PLL or FLL including an up-down counter and a digital-to-analog converter.

6. The injection-locked-type frequency-locked oscillator according to claim 1, wherein
the reference clock signal of the locked loop is injected into the second injection-locked-type signal-controlled oscillator via a pulse generator.

7. The injection-locked-type frequency-locked oscillator according to claim 1, further comprising a frequency offset compensation unit, wherein
the frequency offset compensation unit offsets the oscillation frequency control signal to the first injection-locked-type signal-controlled oscillator and the oscillation frequency control signal to the second injection-locked-type signal-controlled oscillator in order to compensate for an offset of the output frequency signal of the first injection-locked-type signal-controlled oscillator and the second injection-locked-type signal-controlled oscillator.

8. The injection-locked-type frequency-locked oscillator according to claim 7, wherein
the frequency offset compensation unit intermittently offsets the oscillation frequency control signal to the first injection-locked-type signal-controlled oscillator and the oscillation frequency control signal to the second injection-locked-type signal-controlled oscillator.

9. The injection-locked-type frequency-locked oscillator according to claim 8, wherein
the frequency offset compensation unit intermittently offsets the oscillation frequency control signal to the first injection-locked-type signal-controlled oscillator and the oscillation frequency control signal to the second injection-locked-type signal-controlled oscillator at irregular intervals.

10. The injection-locked-type frequency-locked oscillator according to claim 1, wherein
the second injection-locked-type signal-controlled oscillator includes a plurality of injection-locked-type signal-controlled oscillators and a desired frequency signal is output from each injection-locked-type signal-controlled oscillator.
